(19) United States
(12) Patent Application Publication
(10) Pub. No.: US 2025/0301698 A1
(43) Pub. Date: Sep. 25, 2025

(54) SEMICONDUCTOR DEVICE AND MANUFACTURING METHOD THEREOF

(71) Applicant: Hon Young Semiconductor Corporation, Hsinchu City (TW)

(72) Inventor: Kuang-Hao CHIANG, Hsinchu City (TW)

(21) Appl. No.: 18/755,725

(22) Filed: Jun. 27, 2024

(30) Foreign Application Priority Data
Mar. 22, 2024 (TW) 113110874

(51) Int. Cl. H01L 29/78; H01L 21/04; H01L 29/06; H01L 29/08; H01L 29/66

(52) U.S. Cl. CPC H10D 30/665; H01L 21/0465; H10D 30/051; H10D 62/124; H10D 62/153; H10D 64/021

(57) ABSTRACT

A semiconductor device includes a substrate, a drift layer, a junction field-effect transistor region, a well region, a source region, and a gate structure. The drift layer is over the substrate. The junction field-effect transistor region is over the drift layer, and a doping concentration of the junction field-effect transistor region decreases as being far away from the substrate. The well region is over the drift layer and at a side of the junction field-effect transistor region. The source region is in the well region. The gate structure is over the junction field-effect transistor region.

### CROSS-REFERENCE TO RELATED APPLICATION

This application claims priority to Taiwan Application Serial Number 113110874, filed Mar. 22, 2024, which is herein incorporated by reference in its entirety.

### BACKGROUND

### Field of Invention

The present invention relates to a semiconductor device and a manufacturing method thereof.

### Description of Related Art

In planar power transistors, the resistance of the planar power transistors may be composed of the resistance of components in the transistor, such as the resistance of channel, JFET region, substrate, drift layer, contact, etc. Among the components mentioned above, the resistance of the JFET region accounts for a significant part of the resistance of the device.

### SUMMARY

Some embodiments of the present disclosure provide a semiconductor device including a substrate, a drift layer, a junction field-effect transistor region, a well region, a source region, and a gate structure. The drift layer is over the substrate. The junction field-effect transistor region is over the drift layer, and a doping concentration of the junction field-effect transistor region decreases as being far away from the substrate. The well region is over the drift layer and at a side of the junction field-effect transistor region. The source region is in the well region. The gate structure is over the junction field-effect transistor region.

Some embodiments of the present disclosure provide a method of manufacturing a semiconductor device, including forming a drift layer over a substrate, forming a junction field-effect transistor region in the drift layer, wherein a doping concentration of the junction field-effect transistor region decreases as being far away from the substrate, forming a well region in the drift layer and at a side of the junction field-effect transistor region, forming a source region in the well region, and forming a gate structure over the junction field-effect transistor region and the well region.

### BRIEF DESCRIPTION OF THE DRAWINGS

FIGS. 1-5 illustrate cross-section views of a manufacturing process of a semiconductor device in some embodiments of the present disclosure.

FIGS. 6-7 illustrate cross-section views of a manufacturing process of a semiconductor device in some other embodiments of the present disclosure.

### DETAILED DESCRIPTION

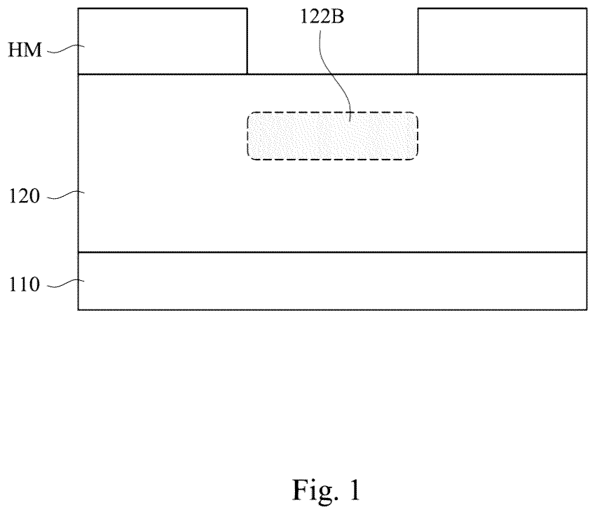

FIGS. 1-5 illustrate cross-section views of a manufacturing process of a semiconductor device in some embodiments of the present disclosure. Referring to FIG. 1, a drift layer 120 is formed over the substrate 110. The substrate 110 and the drift layer 120 may be made of semiconductor material, such as silicon, silicon carbide, the like or combinations thereof. The substrate 110 and the drift layer 120 may have a first conductivity type, and a doping concentration of the substrate 110 is higher than a doping concentration of the drift layer 120. In some embodiments, the conductivity type of the substrate 110 is N type. In some embodiments, the doping concentration of the drift layer 120 is between 10¹⁵ and 10¹⁶/cm³. In some embodiments, the doping concentration of the substrate 110 is between 10¹⁷ and 10¹⁸/cm³. In some embodiments, a doping region of first conductivity type includes N type dopants such as nitrogen, arsenic, and phosphorous.

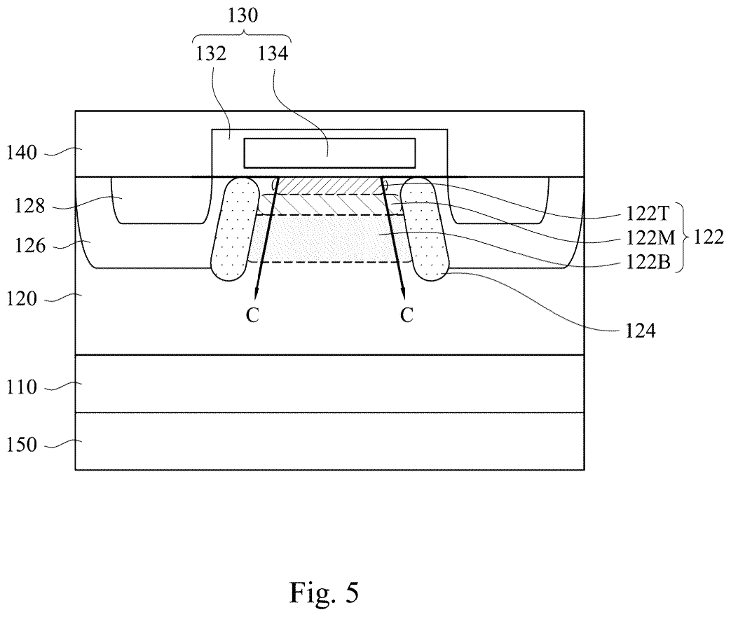

Subsequently, a hard mask layer HM is formed over the drift layer 120, and a bottom portion 122B of the JFET region 122 (FIG. 5) is formed in the drift layer 120 by using the hard mask layer HM as mask. Specifically, an ion implantation process may be performed to implant ions of the first conductivity type into the drift layer 120 to form the bottom portion 122B of the JFET region 122. The energy and the doping concentration of the ion implantation may be controlled, such that the bottom portion 122B of the JFET region 122 is buried in the drift layer 120, and the doping concentration of the bottom portion 122B of the JFET region 122 is higher than the doping concentration of the drift layer 120. In some embodiments, the doping concentration of the ion implantation used for forming the bottom portion 122B of the JFET region 122 is about 10¹⁶/cm³. In some embodiments, the first conductivity type is N type, and the ions of the first conductivity type may be nitrogen or phosphorous. After the process in FIG. 1, there is still a distance between the top of the bottom portion 122B of the JFET region 122 and the top surface of the drift layer 120. In some embodiments, the hard mask layer HM may be made of dielectric material.

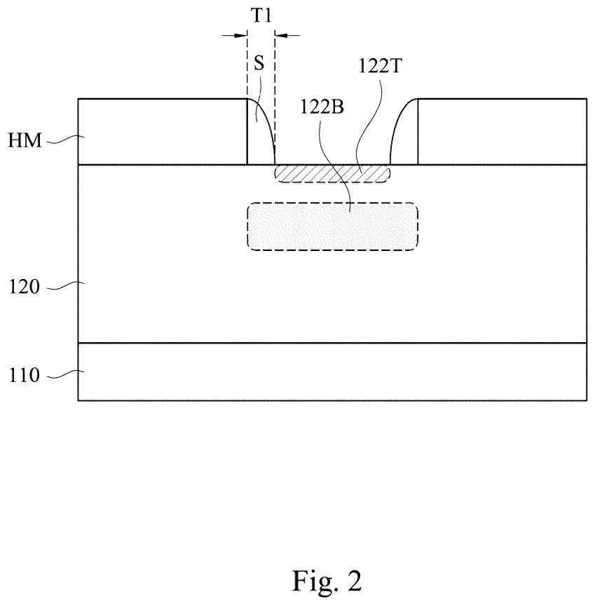

Referring to FIG. 2, a spacer layer S is formed at a sidewall of the hard mask layer HM, and the spacer layer S has a first thickness T1. Subsequently, a top portion 122T of the JFET region 122 is formed in the drift layer 120 by using the hard mask layer HM and the spacer layer S having the first thickness T1 as a mask. Specifically, a conformal spacer material layer is first formed over the hard mask layer HM and the drift layer 120. Subsequently, an anisotropic etching is performed to remove the horizontal portion of the spacer material layer, and the vertical portion of the spacer material layer remains at the sidewall of the hard mask layer HM to form the spacer layer S at the sidewall of the hard mask layer HM. In some embodiments, the first thickness T1 of the spacer layer S is between 0.1 μm and 0.8 μm. In some embodiments, the spacer layer S is made of the dielectric material different from the material of the hard mask layer HM.

Subsequently, an ion implantation process is performed to implant ions of the first conductivity type into the drift layer 120 to form a top portion 122T of the JFET region 122. The energy and the doping concentration of the ion implantation may be controlled, such that the location of the top portion 122T of the JFET region 122 is higher than the location of the bottom portion 122B of the JFET region 122, and the doping concentration of the top portion 122T of the JFET region 122 is lower than the doping concentration of the bottom portion 122B of the JFET region 122. In some embodiments, the top portion 122T of the JFET region 122 is near the surface of the drift layer 120. In some embodiments, the doping concentration of the ion implantation process used for forming the top portion 122T of the JFET region 122 is about 10¹⁴/cm³. In some embodiments, the first conductivity type is N type, and the ions of the first conductivity type may be nitrogen or phosphorous. Since the spacer layer S further covers a portion of the drift layer 120, the width of the top portion 122T of the JFET region 122 is less than the width of the bottom portion 122B of the JFET region 122.

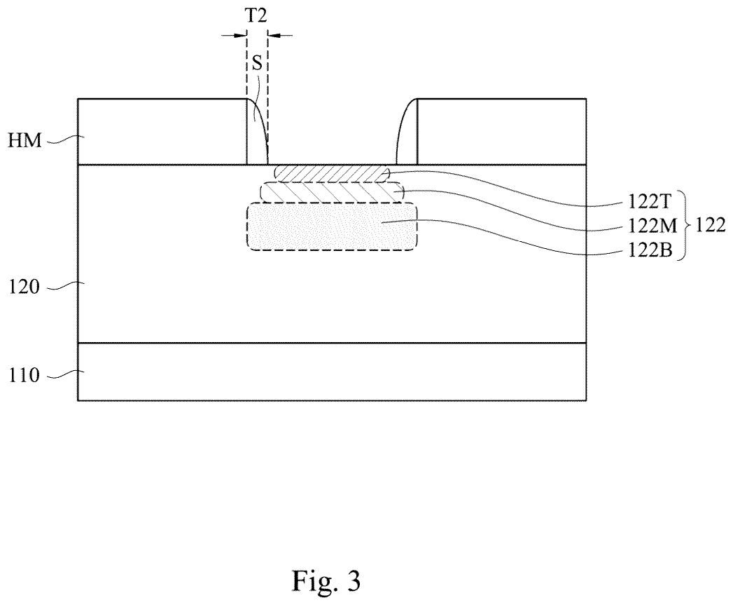

Referring to FIG. 3, the spacer layer S is laterally etched, such that the spacer layer S has a second thickness T2 less than the first thickness T1. Subsequently, the middle portion 122M of the JFET region 122 is formed in the drift layer 120 by using the hard mask layer HM and the spacer layer S having the second thickness T2 as a mask. An ion implantation process may be performed to implant ions of the first conductivity type into the drift layer 120 to form the middle portion 122M of the JFET region 122. The energy and the doping concentration of the ion implantation may be controlled, such that the location of the middle portion 122M of the JFET region 122 is higher than the location of the bottom portion 122B of the JFET region 122 and lower than the location of the top portion 122T of the JFET region 122, and the doping concentration of the middle portion 122M of the JFET region 122 is higher than the doping concentration of the top portion 122T of the JFET region 122 and lower than the doping concentration of the bottom portion 122B of the JFET region 122. In some embodiments, the doping concentration of the ion implantation process used for forming the middle portion 122M of the JFET region 122 is about 10¹⁵/cm³. In some embodiments, the first conductivity type is N type, and the ions of the first conductivity type may be nitrogen or phosphorous. Since the spacer layer S having the second thickness T2 covers smaller range of the drift layer 120, the width of the middle portion 122M of the JFET region 122 is less than a width of the bottom portion 122B of the JFET region 122 and greater than the width of the top portion 122T of the JFET region 122. After the process in FIG. 3, the JFET region 122 having a doping concentration decreasing as being far away from the substrate 100 is formed in the drift layer 120. The JFET region 122 may serve as the current spreading layer, and the mechanism of it will be described later.

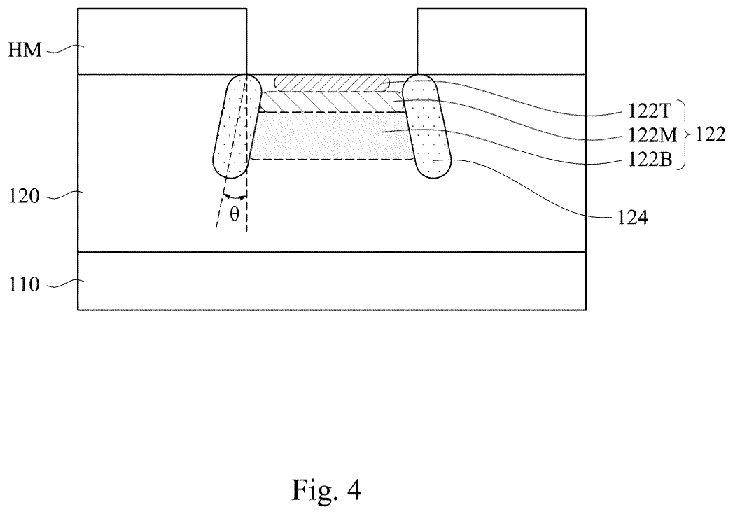

Referring to FIG. 4, after forming the JFET region 122, shielding regions 124 are formed at two sides of the JFET region 122. Specifically, after the process in FIG. 3, the spacer layer S may be removed. Since the spacer layer S is made of dielectric material different from the hard mask layer HM, a suitable etching process may be used to remove the spacer layer S and keep the hard mask layer HM substantially intact. Subsequently, an implantation process is performed at a tilt angle relative to a bottom surface of the substrate 110 to implant ions of the second conductivity type into the drift layer 120 to form the shielding regions 124 at two sides of the JFET region 122. In some embodiments, the shielding regions 124 are tilted inwards, and an angle θ ranging between 7 degrees to 15 degrees is between the shielding region 124 and the normal direction of the substrate 110. Therefore, the resulting shielding region 124 extends along a direction tilted relative to the bottom surface of the substrate 110. The distance between the shielding regions 124 at two sides of the JFET region 122 decreases as being far away from the substrate 110. During the ion implantation process, the ions are implanted into the drift layer 120 at a tilt angle, so the hard mask layer HM may serve as a blocking layer to prevent the shielding regions 124 from forming at the center region of the JFET region 122. In some embodiments, the doping concentration of the shielding region 124 is between 10¹⁹ and 10²⁰/cm³. In some embodiments, the second conductivity type is P type, and the ions of the second conductivity type may be aluminum or boron.

Referring to FIG. 5, well regions 126 are formed in the drift layer 120 and at two sides of the JFET region 122, and source regions 128 are formed in the well region 126. Specifically, the location of the well regions 126 may be defined by a first photomask layer, and an ion implantation process is performed to implant ions of the second conductivity type into the drift layer 120 to form the well regions 126 at two sides of the JFET region 122, and the shielding region 124 is between the well region 126 and the JFET region 122. In some embodiments, the doping concentration of the well regions 126 is between 10¹⁷ and 10¹⁸/cm³. In some embodiments, the second conductivity type is P type, and the ions of the second conductivity type may be aluminum, boron or gallium. Subsequently, the first photomask layer is removed, and the location of the source regions 128 may be defined by a second photomask layer, and an ion implantation process is performed to implant ions of the first conductivity type into the drift layer 120 to form the source regions 128 in the well regions 126. In some embodiments, the doping concentration of the ion implantation process used for forming the source regions 128 is between 10¹⁹ and 10²⁰/cm³. In some embodiments, the first conductivity type is N type, and the ions of the first conductivity type may be nitrogen, phosphorous or arsenic.

Subsequently, a gate structure 130 is formed over the JFET region 122 and the well regions 126. The gate structure 130 may include a gate dielectric layer 132 and a gate layer 134 wrapped by the gate dielectric layer 132. A source electrode 140 is formed over the well regions 126 and the source regions 128. A drain electrode 150 is formed below the substrate 110. In some embodiments, the gate dielectric layer 132 may be made of silicon oxide, silicon nitride or the like. The gate layer 134, the source electrode 140, and the drain electrode 150 may be made of conductive material, such as metal.

The resulting semiconductor device is illustrated in FIG. 5. The semiconductor device includes a substrate 110, a drift layer 120, a JFET region 122, well regions 126, source regions 128, shielding regions 124, a gate structure 130, the source electrode 140, and the drain electrode 150. The drift layer 120 is over the substrate 110. The JFET region 122 is over the drift layer 120. The doping concentration of the JFET region 122 decreases as being far away from the substrate 110, and the width of the JFET region 122 decreases as being far away from the substrate 110. Each of the well regions 126 is over the drift layer 120 and at a side of the JFET region 122. The source regions 128 are in the well regions 126. The shielding regions 124 are at two sides of the JFET region 122, and one of the shielding regions 124 is between the JFET region 122 and the well region 126. The gate structure 130 is over the JFET region 122, the shielding regions 124 and the well regions 126. The source electrode 140 is over the gate structure 130, the well regions 126 and the source regions 128. The drain electrode 150 is below the substrate 110. The drift layer 120, the JFET region 122 and the source regions 128 have the same conductivity type, such as N type. The doping concentration of the JFET region 122 is lower than the doping concentration of the source regions 128, and the doping concentration of the drift layer 120 is lower than the doping concentration of the JFET region 122. The shielding regions 124 and the well regions 126 have the same conductivity type, and the shielding regions 124 and the well regions 126 have different conductivity type from the conductivity type of the drift layer 120, the JFET region 122, and the source regions 128, such as P type. The doping concentration of the shielding regions 124 is higher than the doping concentration of the well regions 126. The doping concentration of the shielding regions 124 is higher than the doping concentration of the JFET region 122.

When operating the semiconductor device in the present disclosure, the path of the electron flow is shown as the arrow C. The doping concentration of the JFET region 122 in the present disclosure decreases as being far away from the substrate 110, and the width of the concentration of the JFET region 122 decreases as being far away from the substrate 110. When the electron flow is closer to the substrate 110 and the drain electrode 150, the doping concentration of the JFET region 122 through which the electron flow passes becomes greater. Since the JFET region 122 having higher doping concentration has better conductivity, as the width of the JFET region 122 increases, the flow range over which the electron flow can be guided becomes larger and larger. The JFET region 122 serves as the current spreading layer accordingly. If the flow range of the electron flow becomes larger as the electron flow is closer to the substrate 110 and the drain electrode 150, the electron flow is not restricted in certain region (i.e. the current is also not restricted in the certain region). The on-resistance of the semiconductor device is reduced accordingly. Moreover, the shielding region 124 has high doping concentration, so the shielding region 124 and the drift layer 120 forms a larger PN junction depletion region is formed, and thus the on-resistance of the semiconductor device is further reduced.

It is noted that the sequence of the formation of the doping regions may be interchanged as long as the doping concentration of the JFET region 122 decreases as being far away from the substrate 110 and/or the width of the concentration of the JFET region 122 decreases as being far away from the substrate 110 in the present disclosure.

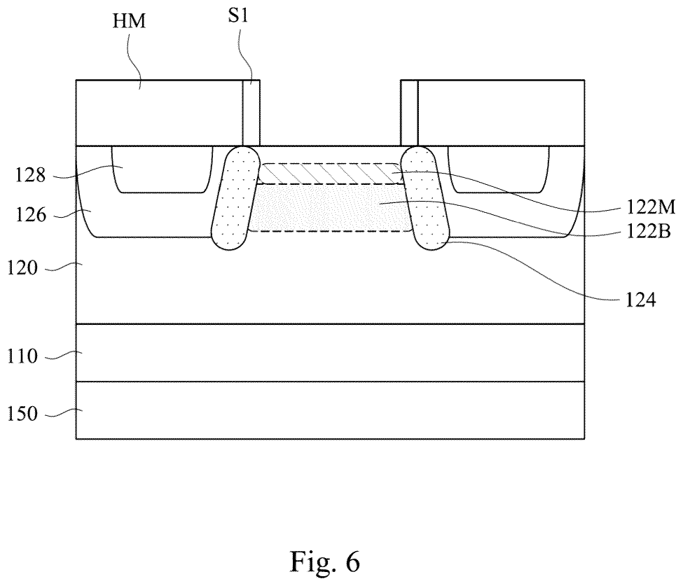

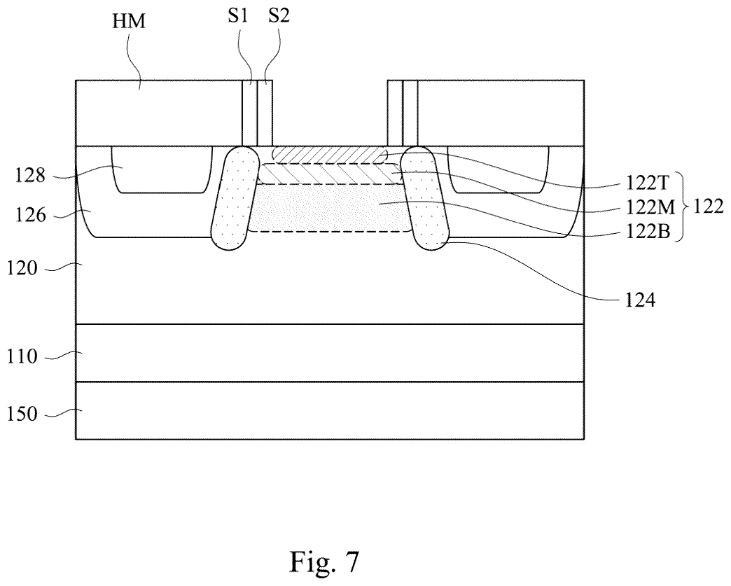

FIGS. 6 and 7 illustrate cross-section views of a semiconductor device in some other embodiments of the present disclosure. The sequence of the formation of the doping regions in FIGS. 6-7 is different from those in FIGS. 1-5. Referring to FIG. 6, a drift layer 120 is first formed over the substrate 110, and well regions 126, shielding regions 124 and source regions 128 are formed in the drift layer 120. The doping concentration and the conductivity types of the substrate 110, the drift layer 120, the well regions 126, the shielding regions 124 and the source regions 128 are as described in FIGS. 1-5, so they are not described here repeatedly.

Subsequently, a hard mask layer HM is formed over the well regions 126 and the source regions 128, and a bottom portion 122B of the JFET region 122 is formed in the drift layer 120 by using the hard mask layer HM as mask. Specifically, an ion implantation process is performed to implant ions of the first conductivity type into the drift layer 120 to form the bottom portion 122B of the JFET region 122. After forming the bottom portion 122B of the JFET region 122, there is still a distance between the top of the bottom portion 122B of the JFET region 122 and the top surface of the drift layer 120. The doping concentration of the ion implantation process used for forming the bottom portion 122B of the JFET region 122 and the conductivity type of the bottom portion 122B of the JFET region 122 are as described in FIG. 2, so they are not described here repeatedly.

Subsequently, a spacer layer S1 is formed at the sidewall of the hard mask layer HM, and the middle portion 122M of the JFET region 122 is formed in the drift layer 120 by using the hard mask layer HM and the spacer layer S1 as mask, and the doping concentration of the middle portion 122M of the JFET region 122 is lower than the doping concentration of the bottom portion 122B of the JFET region 122. Specifically, a conformal spacer material layer is first formed over the hard mask layer HM and the drift layer 120. Subsequently, an anisotropic etching is performed to remove the horizontal portion of the spacer material layer, and the vertical portion of the spacer material layer remains at the sidewall of the hard mask layer HM to form the spacer layer S1 at the sidewall of the hard mask layer HM. Subsequently, an ion implantation process is performed to form the middle portion 122M of the JFET region 122 over the bottom portion 122B of the JFET region 122. After forming the middle portion 122M of the JFET region 122, there is still a distance between the top of the middle portion 122M of the JFET region 122 and the top surface of the drift layer 120. The doping concentration of the ion implantation process used for forming the middle portion 122M of the JFET region 122 and the conductivity type of the middle portion 122M of the JFET region 122 are as described in FIG. 4, so they are not described here repeatedly. Since the drift layer 120 is further covered by the spacer layer S1 during forming the middle portion 122M of the JFET region 122, the width of the middle portion 122M of the JFET region 122 is less than a width of the bottom portion 122B of the JFET region 122.

Referring to FIG. 7, a spacer layer S2 is formed at a sidewall of the spacer layer S1. A top portion 122T of the JFET region 122 is formed in the drift layer 120 by using the hard mask layer HM, the spacer layer S1 and the spacer layer S2 as mask, and the doping concentration of the top portion 122T of the JFET region 122 is lower than the doping concentration of the middle portion 122M of the JFET region 122. Specifically, a conformal spacer material layer is first formed over the hard mask layer HM, the spacer layer S1 and the drift layer 120. Subsequently, an anisotropic etching is performed to remove the horizontal portion of the spacer material layer, and the vertical portion of the spacer material layer remains at the sidewall of the spacer layer S1 to form the spacer layer S2 at the sidewall of the spacer layer S1. Subsequently, an ion implantation process is performed to form the top portion 122T of the JFET region 122 over the middle portion 122M of the JFET region 122. After forming the top portion 122T of the JFET region 122, the top portion 122T of the JFET region 122 is exposed. The ion implantation process used for forming the top portion 122T of the JFET region 122 and the conductivity type of the top portion 122T of the JFET region 122 are as described in FIG. 3, so they are not described here repeatedly. Since the drift layer 120 is further covered by the spacer layer S2 during forming the top portion 122T of the JFET region 122, the width of the top portion 122T of the JFET region 122 is less than the width of the middle portion 122M of the JFET region 122.

Subsequently, the process in FIG. 5 is continued, such as removing the hard mask layer HM, the spacer layer S1, and the spacer layer S2, forming the gate structure 130 over the JFET region 122, forming the source electrode 140 over the well regions 126 and the source regions 128, forming the drain electrode 150 below the substrate 110. The details of the gate structure 130, the source electrode 140 and the drain electrode 150 are as described in FIG. 5, so they are not described here repeatedly.

As a result, in some embodiments as shown in FIGS. 6-7, the doping concentration of the JFET region 122 decreases as being far away from the substrate 110 and/or the width of the concentration of the JFET region 122 decreases as being far away from the substrate 110. The JFET region 122 serves as the current spreading layer accordingly. If the flow range of the electron flow becomes larger as the electron flow is closer to the substrate 110 and the drain electrode 150, the electron flow is not restricted in certain region. The on-resistance of the semiconductor device is reduced accordingly.

What is claimed is:

1. A semiconductor device, comprising:
a substrate;
a drift layer over the substrate;
a junction field-effect transistor region over the drift layer, wherein a doping concentration of the junction field-effect transistor region decreases as being far away from the substrate;
a well region over the drift layer and at a side of the junction field-effect transistor region;
a source region in the well region; and
a gate structure over the junction field-effect transistor region.

2. The semiconductor device of claim 1, wherein a width of the junction field-effect transistor region decreases as being far away from the substrate.

3. The semiconductor device of claim 1, wherein the junction field-effect transistor region has a conductivity type same as a conductivity type of the source region, and the doping concentration of the junction field-effect transistor region is lower than a doping concentration of the source region.

4. The semiconductor device of claim 3, wherein the drift layer has a conductivity type same as the conductivity type of the junction field-effect transistor region, and the doping concentration of the drift layer is lower than a doping concentration of the junction field-effect transistor region.

5. The semiconductor device of claim 1, further comprising:
a shielding region between the well region and the junction field-effect transistor region.

6. The semiconductor device of claim 5, wherein the shielding region has a conductivity type same as a conductivity type of the well region, and the doping concentration of the shielding region is higher than a doping concentration of the well region.

7. A method of manufacturing a semiconductor device, comprising:
forming a drift layer over a substrate;
forming a junction field-effect transistor region in the drift layer, wherein a doping concentration of the junction field-effect transistor region decreases as being far away from the substrate;
forming a well region in the drift layer and at a side of the junction field-effect transistor region;
forming a source region in the well region; and
forming a gate structure over the junction field-effect transistor region and the well region.

8. The method of claim 7, wherein forming the junction field-effect transistor region comprises:
forming a hard mask layer over the drift layer;
forming a bottom portion of the junction field-effect transistor region by using the hard mask layer as a mask;
forming a spacer layer at a sidewall of the hard mask layer, the spacer layer having a first thickness;
forming a top portion of the junction field-effect transistor region by using the hard mask layer and the spacer layer having the first thickness as mask, wherein a doping concentration of the top portion of the junction field-effect transistor region is lower than a doping concentration of the bottom portion of the junction field-effect transistor region;
laterally etching the spacer layer, such that the spacer layer has a second thickness less than the first thickness; and
forming a middle portion of the junction field-effect transistor region by using the hard mask layer and the spacer layer having the second thickness as mask, wherein a doping concentration of the middle portion of the junction field-effect transistor region is higher than the doping concentration of the top portion of the junction field-effect transistor region and lower than the doping concentration of the top portion of the junction field-effect transistor region.

9. The method of claim 7, wherein forming the junction field-effect transistor region comprises:
forming a hard mask layer over the drift layer;
forming a bottom portion of the junction field-effect transistor region by using the hard mask layer as a mask;
forming a first spacer layer at a sidewall of the hard mask layer;
forming a middle portion of the junction field-effect transistor region by using the hard mask layer and the first spacer layer as mask, wherein a doping concentration of the middle portion of the junction field-effect transistor region is lower than a doping concentration of the bottom portion of the junction field-effect transistor region;
forming a second spacer layer at a sidewall of the first spacer layer; and
forming a top portion of the junction field-effect transistor region by using the hard mask layer, the first spacer layer and the second spacer layer, wherein a doping concentration of the top portion of the junction field-effect transistor region is lower than the doping concentration of the middle portion of the junction field-effect transistor region.

10. The method of claim 7, further comprising:
at a tilt angle relative to a bottom surface of the substrate, performing a implantation process to implant ions into the drift layer and forming a plurality of shielding regions.

11. The method of claim 10, wherein the shielding regions have a conductivity type same as a conductivity type of the well region, and the doping concentration of the shielding regions is higher than a doping concentration of the well region.
